(19) United States
(12) Patent Application Publication
(10) Pub. No.: US 2024/0421013 A1
(43) Pub. Date: Dec. 19, 2024

(54) Edge Recess Design for Molded and Fusion or Hybrid Bonded Integrated Circuit

(71) Applicant: Apple Inc., Cupertino, CA (US)

(72) Inventors: Jixuan Gong, San Jose, CA (US); Vidhya Ramachandran, Cupertino, CA (US); Jie-Hua Zhao, Cupertino, CA (US); Young Doo Jeon, San Jose, CA (US); Wei Chen, San Jose, CA (US); Jun Zhai, Cupertino, CA (US)

(21) Appl. No.: 18/585,834

(22) Filed: Feb. 23, 2024

Related U.S. Application Data
(60) Provisional application No. 63/508,845, filed on Jun. 16, 2023.

(51) Int. Cl. H01L 23/31; H01L 23/00; H01L 23/522; H01L 23/58

(52) U.S. Cl. CPC H01L 23/3121; H01L 23/5226; H01L 23/562; H01L 23/585; H01L 24/08; H01L 2224/08225

(57) ABSTRACT

Integrated circuit (IC) structure, IC die structures and methods of fabrication are described in which one or more edge recesses are formed in an IC die. Upon direct bonding to an electronic component, a molding compound can be applied to the bonded structure where the molding compound fills the one or more edge recesses and encroached underneath the IC die and between the IC die and the electronic component.

### RELATED APPLICATIONS

This application claims the benefit of priority of U.S. Provisional Application No. 63/508,845, filed Jun. 16, 2023, which is herein incorporated by reference.

### FIELD

Embodiments described herein relate to semiconductor packaging, and more particularly to molding of directly bonded structures.

### BACKGROUND INFORMATION

The current market demand for portable and mobile electronic devices such as mobile phones, personal digital assistants (PDAs), digital cameras, portable players, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, vertical integration of die in SiP structures has evolved into 2.5D solutions and 3D solutions. In 2.5D solutions the multiple dies may be flip chip bonded on an interposer that may include through vias as well as fan out wiring. Various 3D solutions exist. In one implementation multiple dies may be stacked on top of one another on an SiP substrate, and connected with off-chip wire bonds or solder bumps. In other traditional 3D solutions hybrid bonding using wafer on wafer (WoW) or chip on wafer (CoW) techniques is utilized. In a WoW solution, the top and bottom device area dimensions are exactly matched, and each layer is restricted to one technology node. In a CoW solution multiple top wafers (chips) can be integrated onto the same bottom wafer with defined area and technology node.

Hybrid bonding including metal-metal and oxide-oxide bonding has generally been adopted as a suitable technology for mass production of high-density input/output (I/O) chips with ultra-small pad pitches. A traditional hybrid bonding sequence includes three main operations including oxide-to-oxide initial bonding at room temperature, heating to close dishing gap, and then further heating to compress metal-to-metal bonds. After the hybrid bonding process there can be follow up processing and device finishing operations depending upon the particular application. Modern integrated circuit (IC) fabrication techniques commonly utilize molding compound such as epoxy molding compound to encapsulate the hybrid bonded dies for various reasons including to protect brittle material from mechanical damage and to smooth out a surface to facilitate downstream wafer-level processing.

### SUMMARY

Integrated circuit (IC) structures, IC die structures and methods of fabrication are described in which one or more edge recess are formed in a first bonding surface of an IC die, which is then directly bonded to an electronic component using a suitable technique such as fusion bonding or hybrid bonding. This can then be followed by a molding operation in which a molding compound is flowed into and fills the one or more recesses to help secure the bonded IC die to the electronic component and mitigate stress concentrations at the bonded interface between the IC die and the electronic component.

### BRIEF DESCRIPTION OF THE DRAWINGS

FIG. 1A is a schematic top view illustration of an IC structure including a die directly bonded to an electronic component in accordance with an embodiment.

FIG. 1B is a schematic cross-sectional side view illustration taken along line B-B of FIG. 1A in accordance with an embodiment.

FIG. 2A is a schematic top view illustration of an IC structure including a die directly bonded to an electronic component and encapsulated with a molding compound in accordance with an embodiment.

FIG. 2B is a schematic cross-sectional side view illustration taken along line B-B of FIG. 1A in accordance with an embodiment.

FIG. 3A is a schematic bottom-top view illustration of a die including an edge recess and encapsulated with a molding compound in accordance with an embodiment.

FIG. 3B is a schematic cross-sectional side view illustration of the die of FIG. 3A directly bonded to an electronic component and encapsulated with a molding compound that flows into the edge recess in accordance with an embodiment.

FIG. 3C is a schematic bottom-top view illustration of a die including an edge recess with larger inner chamfer design and encapsulated with a molding compound in accordance with an embodiment.

FIG. 4A is a schematic bottom-top view illustration of a die including an edge recess and encapsulated with a molding compound in accordance with an embodiment.

FIG. 4B is a schematic cross-sectional side view illustration of the die of FIG. 4A directly bonded to an electronic component and encapsulated with a molding compound that flows into the edge recess in accordance with an embodiment.

FIG. 5A is a schematic bottom-top view illustration of a die including a plurality of edge recesses and encapsulated with a molding compound in accordance with an embodiment.

FIG. 5B is a schematic cross-sectional side view illustration of the die of FIG. 5A directly bonded to an electronic component and encapsulated with a molding compound that flows into the plurality of edge recesses in accordance with an embodiment.

FIG. 6A is a schematic bottom-top view illustration of a die including a plurality of edge recesses and encapsulated with a molding compound in accordance with an embodiment.

FIG. 6B is a schematic cross-sectional side view illustration of the die of FIG. 6A directly bonded to an electronic component and encapsulated with a molding compound that flows into the plurality of edge recesses in accordance with an embodiment.

FIG. 7 is a schematic cross-sectional side view illustration of an integrated circuit structure including a die directly bonded to an electronic component and embedded within a molding compound layer in accordance with an embodiment.

FIG. 8 is a schematic cross-sectional side view illustration of an integrated circuit structure including a die directly bonded to an electronic component and underfilled with a molding compound in accordance with an embodiment.

FIG. 9 is a schematic cross-sectional side view illustration of an integrated circuit structure including a die directly bonded to an electronic component and embedded within a molding compound layer in accordance with an embodiment.

FIG. 10A is a schematic cross-sectional side view illustration of an integrated circuit structure including a die directly bonded to an electronic component including a shallow edge recess partially through a thickness of the electronic component in accordance with an embodiment.

FIG. 10B is a schematic cross-sectional side view illustration of an integrated circuit structure including a die directly bonded to an electronic component including a deep edge recess partially through a thickness of the electronic component in accordance with an embodiment.

FIG. 10C is a schematic cross-sectional side view illustration of an integrated circuit structure including a die directly bonded to an electronic component including an edge recess completely through a thickness of the electronic component in accordance with an embodiment.

FIG. 10D is a schematic cross-sectional side view illustration of an integrated circuit structure including a die directly bonded to an electronic component with edge recesses formed in both the IC die and the electronic component in accordance with an embodiment.

FIG. 11 is a schematic cross-sectional side view illustration taken along section A-A or section B-B of the integrated circuit structure of FIG. 12 or section C-C of the integrated circuit structure of FIG. 13 in accordance with an embodiment.

FIG. 12 is a schematic bottom-top plan view illustration of an integrated circuit structure including a plurality of dies directly bonded to an electronic component including a global component edge recess in accordance with an embodiment.

FIG. 13 is a schematic bottom-top plan view illustration of an integrated circuit structure including a plurality of dies directly bonded to an electronic component including a plurality of local component edge recesses in accordance with an embodiment.

FIG. 14 is a schematic cross-sectional side view illustration of an integrated circuit structure including a die set directly bonded to an electronic component including component edge recesses in accordance with an embodiment.

FIGS. 15A-15K are schematic cross-sectional side view illustrations of a sequence for fabricating an integrated circuit structure in accordance with an embodiment.

### DETAILED DESCRIPTION

Embodiments describe integrated circuit (IC) structures, IC die structures and methods of fabrication in which one or more edge recesses are formed in a die to mitigate stress concentration of a molded, and hybrid or fusion bonded interface. In an embodiment, an IC structure includes an IC die that is bonded directly to another electronic component, such as a second die, interposer, etc., through fusion bonding or hybrid bonding with metal-metal and dielectric-dielectric bonds. The IC die may include a first bonding surface, a first lateral edge and a first edge recess in the first bonding surface, which is bonded directly to a second bonding surface of the electronic component. Both bonding surfaces may be planar to facilitate fusion or hybrid bonding. A molding compound, such as an epoxy molding compound, is then applied so that it spans across the electronic component and the first lateral edge of the IC die and fills the first edge recess. Thus, the molding compound within the first edge recess encroaches underneath the IC die and between the IC die and the electronic component.

In another embodiment, an integrated circuit structure includes an IC that includes a first bonding surface and a first perimeter edge, and an electronic component that includes a second bonding surface and a component edge recess in the second bonding surface. The second bonding surface may be directly bonded to the first bonding surface. Both bonding surfaces may be planar to facilitate fusion or hybrid bonding. A molding compound is then applied so that it spans across the electronic component and the first perimeter edge and fills the component edge recess.

In one aspect, it has been observed that molding compound material such as epoxy molding compound (EMC) has a much lower elastic modulus and higher coefficient of thermal expansion (CTE) than the IC die structure(s) it encapsulates, and this change in elastic modulus and CTE from the bonded IC die structure(s) to the surrounding EMC can cause high stress concentrations near the IC die edges and corners of the bonding interface. In particular high peeling stress concentrations may form when the bonded structure is trying to bend due to thermal or mechanical loadings, such as with EMC expansion at elevated temperatures. Additionally, high shear stress concentrations may form as the bonded structure tries to shrink or expand together with other packaging and system components (e.g., substrate, printed circuit board, etc.).

In another aspect it has been observed that an incoming IC die may have a certain level of intrinsic warpage due to residual stress in a back-end-of-the-line (BEOL) build-up structure and bonding interface layer material that is used for fusion or hybrid bonding. It has been observed that it can be challenging to flatten the IC die edges and corners during direct bonding processes such as fusion and hybrid bonding.

In accordance with embodiments the IC die edges and corners can have an overhang region formed by one or more edge recesses formed in the IC dies and/or electronic component to which the IC dies are bonded. When bonding the IC die to an electronic component the internal bonding interface can be more easily closed with backside clamping pressure. In the subsequent molding process the molding compound material, such as EMC can flow into the edge recess volumes, further functioning as a buffer and glue layer. When mechanical or thermal loading is applied, the EMC can absorb a large portion of the stresses while protecting the bonding interface inside. Furthermore, when subjected to thermal loadings, expansion of the EMC outside lateral edges of the IC dies may press down the EMC within the edge recess volumes (e.g., cantilever portions) providing clamping force to protect the bonding interface integrity.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

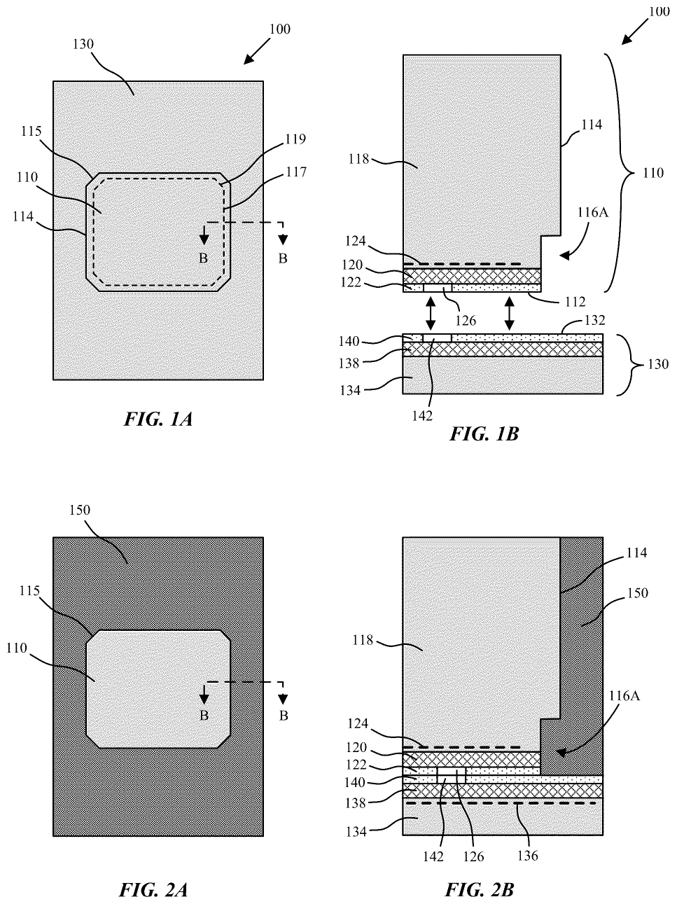

Referring now to FIGS. 1A-1B, FIG. 1A is a schematic top view illustration of an IC structure 100 including an IC die 110 directly bonded to an electronic component 130 in accordance with an embodiment; FIG. 1B is a schematic cross-sectional side view illustration taken along line B-B of FIG. 1A in accordance with an embodiment. The electronic component 130 in accordance with embodiments can be a variety of components such as a second die, interposer, etc. Direct bonding may be accomplished using suitable techniques such as fusion bonding or hybrid bonding with metal-metal and dielectric-dielectric bonds, such that corresponding planarized bonding surfaces 112, 132 are directly bonded to one another at (and diffused across) a bonding interface.

As shown, the IC die 110 may include a first bonding surface 112, a first lateral edge 114 and a first edge recess 116A in the first bonding surface 112 which is bonded directly to a second bonding surface 132 of the electronic component 130. Corners of the IC die 110 may also include chamfers 115, or otherwise tapered edges to help prevent stress accumulation at the corners of the bonding interface. Furthermore, the chamfers 115 along the IC die edges (including lateral edges 114) can be promulgated to the interior edges 117 of the first edge recesses 116A, where chamfers 119 can also be formed at the corresponding corners. In some embodiments, the chamfers 119 can be formed irrespective to whether chamfers 115 were formed.

The chamfers and/or one or more edge recesses in accordance with embodiments can be formed by any combination of patterning and etching techniques. For example, plasma etching may be used to form the chamfers and/or one or more edge recesses in accordance with embodiments.

To facilitate fusion and hybrid bonding, both bonding surfaces may be planarized, such as with chemical mechanical polishing (CMP). In an exemplary embodiment the IC die 110 includes a semiconductor layer 118, a back-end-of-the-line (BEOL) build-up structure 120 on the semiconductor layer, and a bonding interface layer 122 on the BEOL build-up structure 120. Semiconductor layer 118 may include a bulk layer and epitaxial device layer, for example, in which devices 124 such as transistors, etc. may optionally be formed. The BEOL build-up structure 120 may include a plurality of metal wiring layers and dielectric layers, commonly referred to as interlayer dielectrics (ILD), as common in microelectronic manufacturing. The bonding interface layer 122 in accordance with embodiments may be formed of an insulating material, such as oxide (e.g., silicon oxide, silicon nitride, silicon carbon nitride, etc.) and may optionally include metal bond pads 126 (e.g., vias, plugs). The first (planar) bonding surface 112, may span a plurality of metal bond pads 126 and the bonding interface layer 122 for hybrid bonding, or only a bonding interface layer 122 for fusion bonding.

In the particular embodiment illustrated the electronic component 130 may be a second die. For example, in wafer-level processing the plurality of second dies can be patterned in a silicon wafer, onto which a plurality of IC dies 110 are bonded in a chip-on-wafer (CoW) assembly process. In such an embodiment, the dies can be bonded face-to-face. For example, the electronic component may also include a semiconductor layer 134 into which devices 136 are formed, BEOL build-up structure 138, bonding interface layer 140, and metal bond pads 142 similar as the IC die 110. In such a configuration the dies can be bonded face-to-face, though this is not required and can be bonded face-to-back, or back-to-face. Additionally, in some embodiments the electronic component 130 may be an interposer or other structure as opposed to a second die.

The IC die 110, as well as the electronic component 130, can be a variety dies, such as system-on-chip (SOC), graphics processing unit (GPU), central processing unit (CPU), artificial intelligence (AI), machine learning logic, radio-frequency (RF) baseband processor, radio-frequency (RF) antenna, signal processors, power management integrated circuit (PMIC), logic, memory, photonics, biochips, low speed and/or high speed input/output (HSIO), cache, a silicon interconnect and any combinations thereof. The silicon interconnect, for example, can be a chiplet including lateral routing for die-to-die connections. In some embodiments, no logic or passive devices are included in the silicon interconnect, and the silicon interconnect is used primarily for fine die-to-die wiring. In other embodiments capacitors or logic can be included within the silicon interconnect in combination with the fine die-to-die wiring.

Referring now to FIGS. 2A-2B; FIG. 2A is a schematic top view illustration of an IC structure including an IC die directly bonded to an electronic component and encapsulated with a molding compound in accordance with an embodiment; FIG. 2B is a schematic cross-sectional side view illustration taken along line B-B of FIG. 1A in accordance with an embodiment. In some embodiments, the molding compound 150 is formed as an overmolding layer in which the IC dies 110 are fully covered. This may optionally be followed by a planarization operation to thin the molded surface or expose the back sides of the IC dies 110. In other embodiments, the molding compound 150 is formed as an underfill material that also wicks along the lateral edges 114 of the IC dies 110. As shown, the molding compound 150 spans the second bonding surface 132 of the electronic component 130 and the first lateral edge 114 of the IC die 110 and fills the first edge recess 116A. Thus, the molding compound within the first edge recess 116A encroaches underneath the IC die and between the IC die and the electronic component. The ability to fill the first edge recess 116A may depend upon factors such as aspect ratio (width:depth) of the first edge recess 116A, viscosity of the molding compound materials as applied, etc. Dimensions may also affect ability to flatten the IC die 110 edges and corners, bonding interface stress concentration near edges and corners of the IC die 110, BEOL build-up structure 120 crack risk, and potential for molding compound 150 void (within the edge recesses) and crack risk.

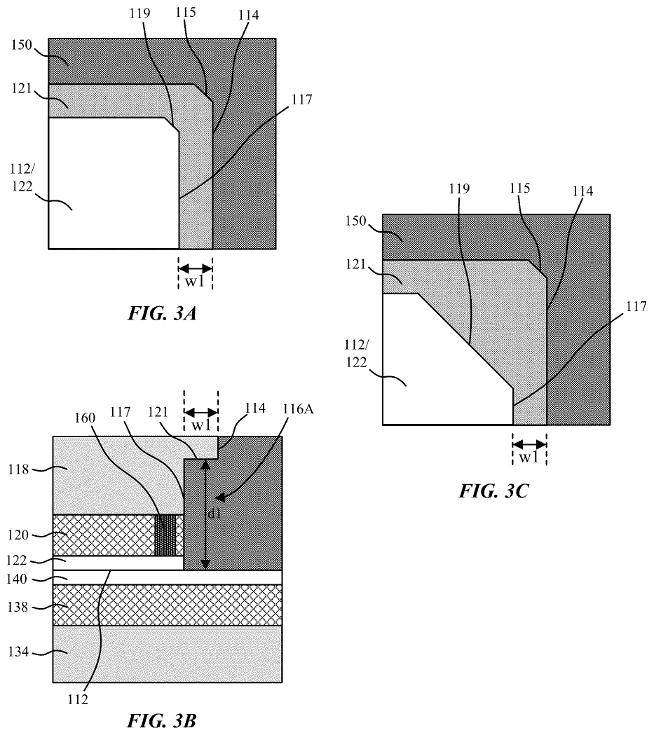

Referring now to FIGS. 3A-3C; FIG. 3A is a schematic bottom-top view illustration of an IC die including an edge recess and encapsulated with a molding compound in accordance with an embodiment; FIG. 3B is a schematic cross-sectional side view illustration of the IC die of FIG. 3A directly bonded to an electronic component and encapsulated with a molding compound that flows into the edge recess in accordance with an embodiment; FIG. 3C is a schematic bottom-top view illustration of a die including an edge recess with larger inner chamfer design and encapsulated with a molding compound in accordance with an embodiment. In the particular embodiment illustrated the first edge recess 116A is characterized by a first width (w1) that extends from the first lateral edge 114 to a first interior edge 117, and a first depth (d1) that extends from the first bonding surface 112 to a first roof 121. In the particular embodiment illustrated in FIG. 3B, the first depth (d1) of the first edge recess 116A spans the bonding interface layer 122, the BEOL build-up structure 120, and into the semiconductor layer 118 of the IC die 110. The BEOL build-up structure 120 may additionally include a seal ring 160 adjacent to the first interior edge 117, and the first width (w1) of the first edge recess 116A does not extend to the seal ring 160. In such an embodiment, the first width (w1) may be a shorter distance than the first depth (d1) due to extension of the first depth (d1) into the semiconductor layer 118. The seal ring may be present to protect from moisture ingress, as well as to provide physical protection to the BEOL build-up structure 120, and commonly brittle ILD materials.

In the embodiment illustrated in FIG. 3B the first depth (d1) is shown as being a greater distance than the first width (w1), though this is not required and the dimensions in FIG. 3B may be reversed, or the same. Exemplary dimensions are provided in Table I below.

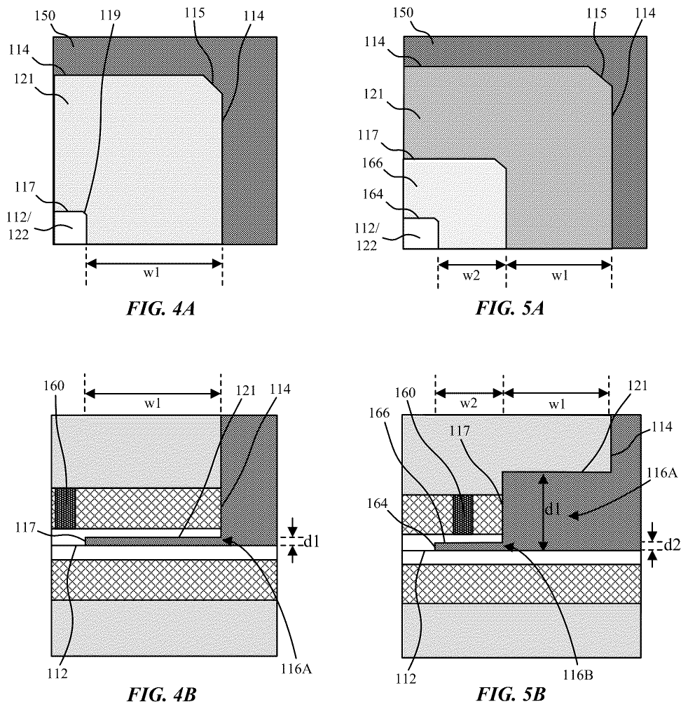

TABLE 1
Example Edge Recess Dimensions

| | First Edge | | First Edge | | Second Edge | Second Edge |
|---|---|---|---|---|---|---|
| | Recess width | | Recess depth | | Recess width | Recess depth |
| | (w1) | | (d1) | | (w2) | (d2) |
| FIGS. 3A-3B | <15 | μm | >50 | μm | N/A | N/A |
| FIGS. 4A-4B | >50 | μm | <3 | μm | N/A | N/A |
| FIGS. 5A-5B | ~100 | μm | ~20-30 | μm | ~20-40 μm | <3 μm |

FIG. 3C is similar to that of FIG. 3A with a larger inner chamfer 119 design along the first bonding surface 112. The larger inner chamfer design may facilitate additional stress reduction as the IC die corners where highest stress is normally located. It has been observed that a configuration such as those illustrated in FIGS. 3A-3C may require minimal IC die 110 area and provide good protection against BEOL build-up structure crack risk as well as molding compound void and crack risk. However, consumption of minimal IC die 110 area may be met with moderate gains in ability to flatten the IC die 110 edges and corners and reduce interface stress concentration near the edges and corners.

Referring to FIGS. 4A-4B; FIG. 4A is a schematic bottom-top view illustration of an IC die including an edge recess and encapsulated with a molding compound in accordance with an embodiment; FIG. 4B is a schematic cross-sectional side view illustration of the IC die of FIG. 4A directly bonded to an electronic component and encapsulated with a molding compound that flows into the edge recess in accordance with an embodiment. FIGS. 4A-4B are similar to those of FIGS. 3A-3B, with differing dimensions, and hence location, of the first edge recess 116A. In the illustrated embodiment, the first roof 121 of the first edge recess is underneath the BEOL build-up structure 120. For example, the first roof 121 may be within the bonding interface layer 122 of the IC die 110 or, through the bonding interface layer 122, stopping on an etch stop layer. On the BEOL build-up structure 120. As shown in FIG. 4B, the first width (w1) of the first edge recess 116A does not extend to the seal ring 160. In this manner the seal ring 160 may be interior to the first interior edge 117, and may provide protection to moisture ingress from the molding compound 150. In an exemplary embodiment, the first width (w1) is shown as being a greater distance than the first depth (d1). While extension first width (w1) may consume additional IC die 110 area compared to the configuration of FIGS. 3A-3B, the thinner first depth (d1) may help mitigate bonding interface stress concentrations near the edges and corners, and also help facilitate flattening of the IC die 110 edges and corners. Depending upon particular arrangement, a minimum depth (d1) may be maintained to ensure molding compound flows into the first edge recess 116A to mitigate void and crack formation therein.

In some embodiments a plurality of edge recesses may be formed in the IC die 110. Referring to FIGS. 5A-5B; FIG. 5A is a schematic bottom-top view illustration of an IC die including a plurality of edge recesses and encapsulated with a molding compound in accordance with an embodiment; FIG. 5B is a schematic cross-sectional side view illustration of the IC die of FIG. 5A directly bonded to an electronic component and encapsulated with a molding compound that flows into the plurality of edge recesses in accordance with an embodiment. Generally, the embodiments of FIGS. 5A-5B share similarities with those of FIGS. 3A-3B and FIGS. 4A-4B. Specifically, the first depth (d1) of the first edge recess 116A spans the bonding interface layer 122, the BEOL build-up structure 120 and into the semiconductor layer 118 of the IC die 110 such that the roof 121 of the first edge recess 116A is in the semiconductor layer 118. Furthermore, the BEOL build-up structure 120 may include a seal ring 160 adjacent to the first interior edge 117, and the first width (w1) of the first edge recess does not extend to the seal ring 160. The first edge recess 116A may be similar to that of FIGS. 3A-3B, with certain differences in dimensions. The embodiment illustrate din FIGS. 5A-5B may additionally include a second edge recess 116B characterized by a second width (w2) that extends from the first interior edge 117 of the first edge recess 116A to a second interior edge 164, and a second depth (d2) that extends from the first bonding surface 112 to a second roof 166. As shown, the molding compound 150 fills both the first edge recess 116A and the second edge recess 116B. In an embodiment, the BEOL build-up structure 120 includes a seal ring 160 adjacent to the first interior edge 117, and the second width (w2) of the second edge recess 116B may or may not extend underneath the seal ring 160.

The particular embodiment illustrated in FIGS. 5A-5B may combine several benefits of the embodiments illustrated in FIGS. 3A-3B and FIGS. 4A-4B. Specifically, inclusion of the second edge recess 116B can help mitigate bonding interface stress concentration near edges and corners and facilitate flattening of the IC die edges and corners during bonding with shorter w2 comparing with w1 in FIGS. 4A-4B. Furthermore, inclusion of the seal ring closer to the first interior edge 117 can help preserve BEOL build-up structure 120 mechanical integrity and mitigate crack risk therein. Furthermore, the combination of the first edge recess 116A with the shorter second edge recess 116B can help direct flow of molding compound 150 and mitigate molding compound void and crack risk.

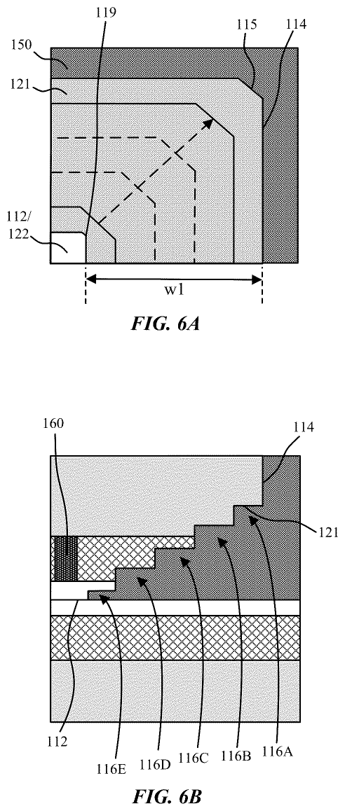

A variety of edge recess designs can be integrated in accordance with embodiments. Referring now to FIGS. 6A-6B, FIG. 6A is a schematic bottom-top view illustration of a die including a plurality of edge recesses and encapsulated with a molding compound in accordance with an embodiment; FIG. 6B is a schematic cross-sectional side view illustration of the die of FIG. 6A directly bonded to an electronic component and encapsulated with a molding compound that flows into the plurality of edge recesses in accordance with an embodiment. As shown, a plurality of edge recess 116A, 116B, 116C, 116D, 116E, etc. can be formed. While a total of five edge recesses are illustrated in FIGS. 6A-6B, embodiments are not so limited and it is understood any number can be provided, with their depths, widths, and chamfer sizes being designed for consideration of both stress reduction and design/manufacturing requirements.

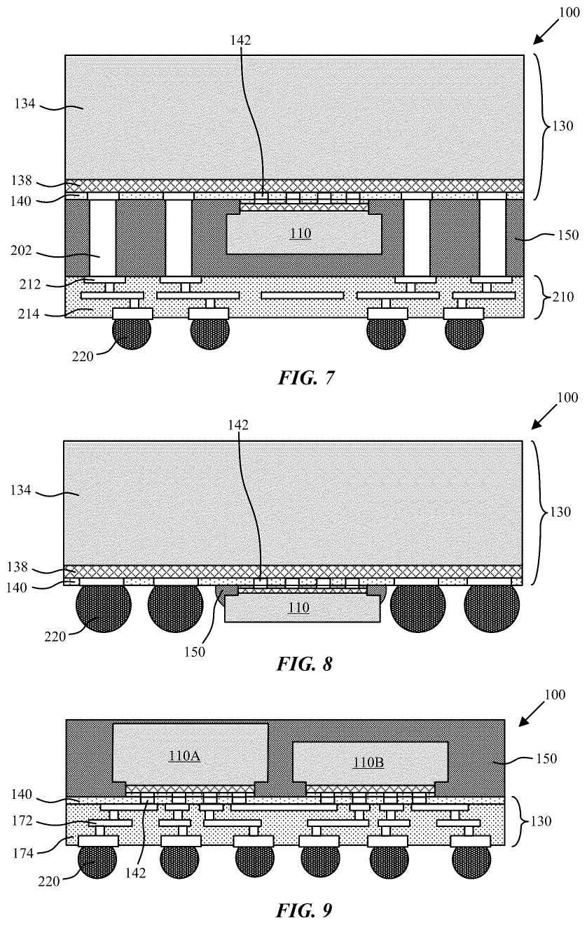

The edge recess configurations in accordance with embodiments can be implemented into a variety of integrated circuit structure configurations. While not exhaustive, several exemplary implementations are illustrated in FIGS. 7-9 to provide additional context.

FIG. 7 is a schematic cross-sectional side view illustration of an IC structure 100 including an IC die 110 directly bonded to an electronic component 130 and embedded within a molding compound 150 layer in accordance with an embodiment. In the exemplary embodiment illustrated, the IC die 110 may be hybrid bonded to component 130, which may be in wafer form prior to dicing. Prior to bonding or after bonding, a plurality of vertical pillars 202 (e.g., copper pillars) may be formed, on the component 130 followed by overmolding with molding compound 150 and planarization. Alternatively, the vertical pillars 202 can be formed after overmolding. An optional routing layer 210 including one or more metal routing layers 212 and dielectric layers 214 may be formed, followed by application of solder bumps 220 and singulation into multiple IC structures 100 (e.g., packages).

FIG. 8 is a schematic cross-sectional side view illustration of an IC structure 100 including an IC die 110 directly bonded to an electronic component 130 and underfilled with a molding compound 150 in accordance with an embodiment. In such an embodiment, the molding compound 150 may flow similarly as described with previous embodiments. While further overmolding is possible, in the embodiment illustrated a plurality of solder bumps 220 may then be placed laterally adjacent the IC die 110 for further integration.

FIG. 9 is a schematic cross-sectional side view illustration of an IC structure 100 including one or more IC dies 110A, 110B directly bonded to an electronic component 130 and embedded within a molding compound 150 layer in accordance with an embodiment. In particular, FIG. 8 represents an embodiment in which the IC die(s) 110A, 110B are directly bonded to an interposer rather than another die. For example, the interposer, or electronic component 130, can include bonding interface layer 140 and metal bond pads 142 similar to previous embodiments, as well as one or more metal routing layers 172 and dielectric layers 174. The interposer, or electronic component 130, can be a cored substrate, a coreless substrate, rigid, flexible, etc. In an embodiment, the interposer, or electronic component 130, includes through vias such as through silicon vias (TSVs), through glass vias, etc.

Up until this point embodiments have been described in which edge recesses are formed within the IC dies. Similar edge recesses may also be formed within the variety of electronic components to facilitate a similar overhang arrangement. Such component edge recesses may be formed completely through a thickness of the electronic component or partially through a thickness of the electronic component. Furthermore, the component edge recesses can be isolated, or over a large area such as surrounding one or more perimeter edges of the IC die or die set. The component edge recesses may also be chamfered as the corners. The depths, widths, and chamfer sizes of the electronic components can be designed for consideration of both stress reduction and design/manufacturing requirements.

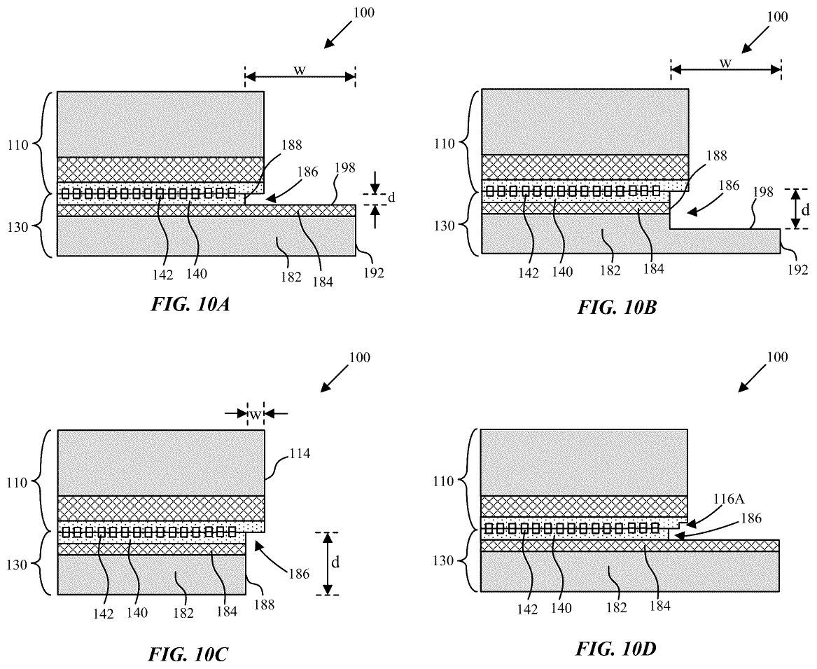

Referring now to FIGS. 10A-10B schematic cross-sectional side view illustrations are provided of an integrated circuit structure 100 including an IC die 110 directly bonded to an electronic component 130 including an edge recess 186 partially through a thickness of the electronic component in accordance with an embodiment. In the exemplary embodiments illustrated the electronic component 130 can include a base substrate 182 such as a semiconductor (e.g., silicon) substrate, glass substrate, polymer substrate, etc. The electronic component can be purely passive and provide electrical routing, and may also include active devices (e.g., transistors) and/or passive devices (e.g., capacitors, inductors, resistors). For example, active devices can optionally be formed in a semiconductor base substrate 182. A routing layer 184 can optionally be formed over the base substrate 182. For example, the routing layer 184 may be similar to a BEOL build-up structure, or include one or more dielectric layer(s) and metal wiring layer(s). The electronic component 130 can additionally include a bonding interface layer 140, and metal bond pads 142 as previously described.

The component edge recess 186 may be characterized by a first width (w) that extends from the component lateral edge 192 (which may be a package lateral edge, an opposite edge of an interior component edge recess, or even an IC die perimeter edge 114 as shown in FIG. 10C) to a component interior edge 188, and a first depth (d) that extends from the second bonding surface to a floor 198. In each of the configurations illustrated the component edge recess 186 can help reduce the hybrid or fusion bond delamination risk of the IC die 110 by shifting a high stress region into a non-critical and high strength region in the electronic component 130. In the embodiment illustrated in FIG. 10A the component edge recess 186 may be a shallow recess extending through the bonding interface layer 140 with the floor formed as part of the routing layer 184. Such a configuration may allow for larger fan-out routing area. In the embodiment illustrated in FIG. 10B the component edge recess 186 may be a deep recess extending through the bonding interface layer 140 and routing layer 184, with the floor formed as part of the base substrate 182.

In the embodiments illustrated in FIGS. 10A-10B the electronic component (e.g., interposer) may have a larger footprint as the IC die or die set bonded to the electronic component. Referring not to FIG. 10C a schematic cross-sectional side view illustration is provided of an integrated circuit structure 100 including an IC die 110 directly bonded to an electronic component 130 including a component edge recess 186 completely through a thickness of the electronic component in accordance with an embodiment. Such a configuration may minimize bending of the electronic component 130 by removing the overhang.

FIG. 10D is a schematic cross-sectional side view illustration of an integrated circuit structure 100 including an IC die 110 directly bonded to an electronic component 130 with edge recesses formed in both the IC die and the electronic component in accordance with an embodiment. As shown, the IC die 110 may include at least one edge recess such as first edge recess 116A as previously described, while the electronic component 130 also includes a component edge recess 186, such as that described with regard to FIGS. 10A-10C.

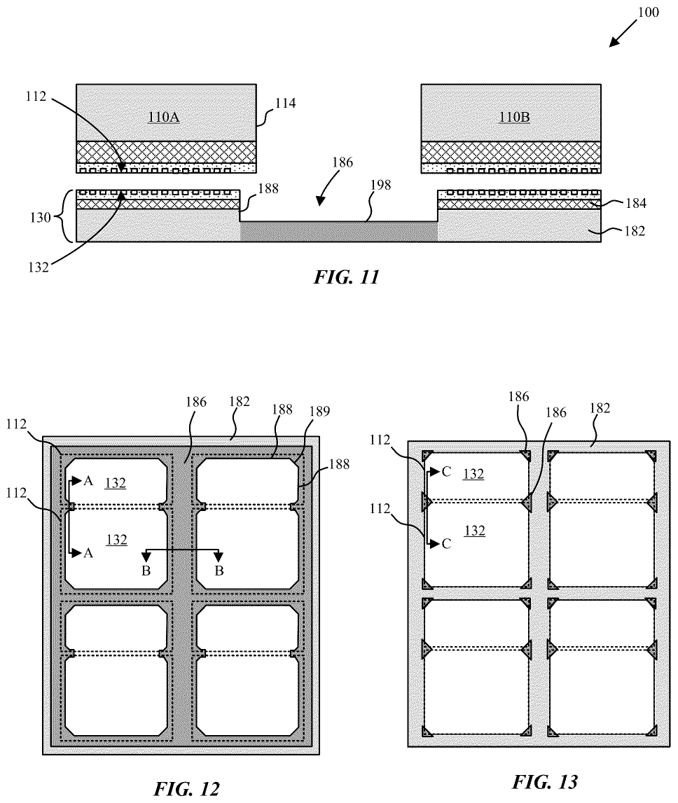

Referring now to FIGS. 11-13, FIG. 11 is a schematic cross-sectional side view illustration taken along section A-A or section B-B of the integrated circuit structure of FIG. 12 or section C-C of the integrated circuit structure of FIG. 13 in accordance with an embodiment; FIG. 12 is a schematic bottom-top plan illustration of an integrated circuit structure including a plurality of dies directly bonded to an electronic component including a global component edge recess in accordance with an embodiment; FIG. 13 is a schematic bottom-top plan view illustration of an integrated circuit structure including a plurality of dies directly bonded to an electronic component including a plurality of local component edge recesses in accordance with an embodiment. As shown, each configuration may be a partially fabricated structure prior to or after bonding of the IC dies 110A, 110B with the electronic component 130. Referring to FIG. 12 in combination with FIG. 11 the component edge recess 186 can be a global recess surrounding multiple IC dies in a die set. Each die set may be subsequently singluated (diced) from the bonded structure after further processing to form discrete packages. For illustrative purposes the component edge recess 186 floor 198 area is illustrated with darker shading and the component bonding surface 132 is illustrated in white, while the IC die bonding surface 112 is illustrated in dashed line. In the embodiment illustrated in FIG. 12 the global component edge recess 186 can surround one or more perimeter edges 114 of the one or more IC dies. The bonding surface 132 area formed by etching of component edge recesses 186 may be any suitable shape, and may also include chamfers 189 adjacent corners where component interior edges 188 meet. As shown, each IC die may be generally rectangular with four perimeter edges 114 (not including any potential chamfers at the corners, for example). The global component edge recess 186 may completely surround the entire perimeter edges 114 (and optional chamfers) of each IC die, or each IC die set, for example, as shown in FIG. 12 where four two-IC die sets are shown. In another configuration illustrated in FIG. 13 a plurality of local (separate) component edge recesses 186 can be formed, for example underneath one or more IC die corners.

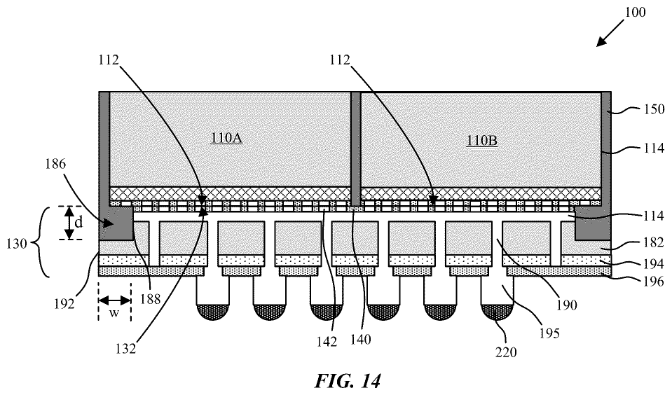

FIG. 14 is a schematic cross-sectional side view illustration of an integrated circuit structure 100 including a die set of IC dies 110A, 110B directly bonded to an electronic component 130 including component edge recesses 186 in accordance with an embodiment. As shown, each of the IC dies 110A, 110B can include a first bonding surface 112 and a first perimeter edge 114. The electronic component 130 (e.g., interposer) includes a second bonding surface 132 and one or more component edge recesses 186 in the second bonding surface. The first bonding surfaces 112 of the IC dies 110A, 110B are bonded directly to the second bonding surface 132 of the electronic component 130 such that a portion of the first bonding surfaces 112 overhangs the one or more component edge recesses 186, and a molding compound is applies so that it spans across the electronic component and the first perimeter edge 114 of the one or more IC dies 110A, 110B and fills the component edge recess 186.

The electronic component 130 in accordance with embodiments may be a variety of objects including another IC die, interposer, etc. In the illustrated embodiment, the electronic component 130, or interposer, includes a base substrate 182, routing layer 184, bonding interface layer 140, and metal bond pads 142 as previously described. A plurality of through vias 190, such as through silicon vias (TSVs), can extend through a thickness of the base substrate 182 and be electrically connected with landing terminals 195 (e.g., stud bumps, landing pads) and solder bumps 220 on a back side of the electronic component opposite the second bonding surface 132. A back side of the base substrate 182 may have additional passivation layers 194, 196. Similar to the die set arrangement of FIG. 12, in an embodiment the component edge recess 186 shown in FIG. 14 completely surrounds the first perimeter edges 114 of the IC dies 110A, 110B. Alternatively, similar to the die set arrangement of FIG. 13, the component edge recesses 186 in FIG. 14 are a plurality of local edge recesses located adjacent corners of the IC dies 110A, 110B.

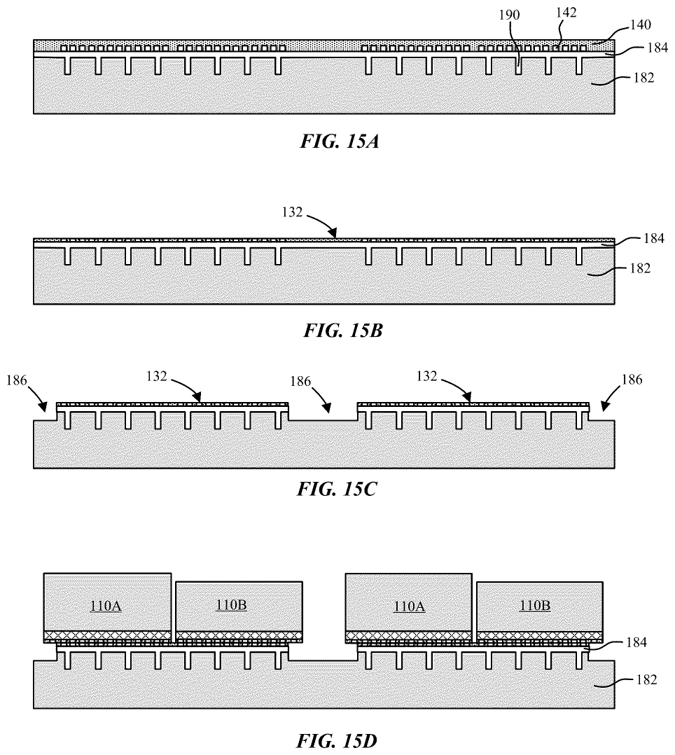

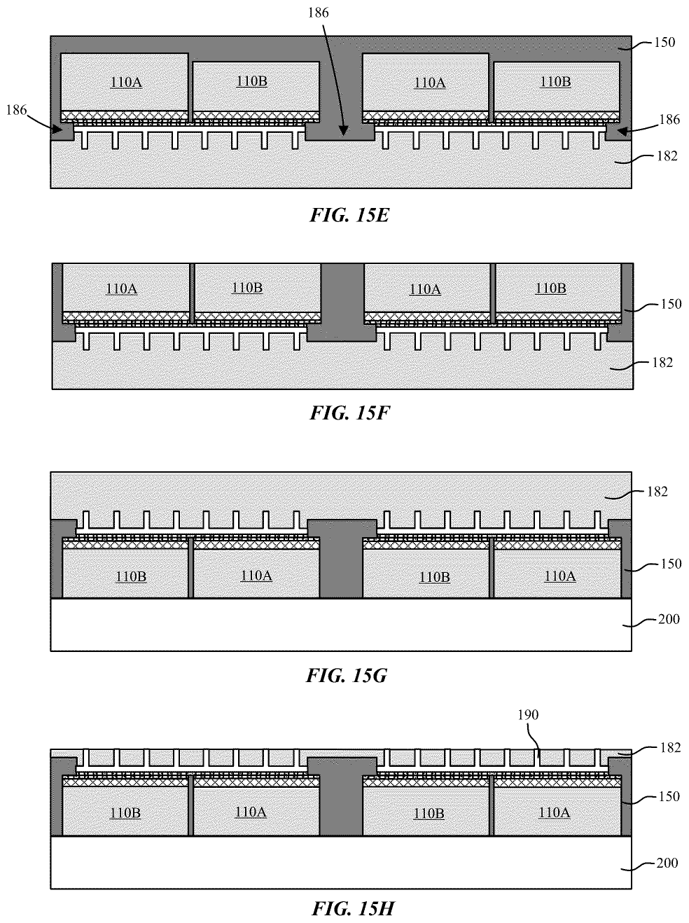

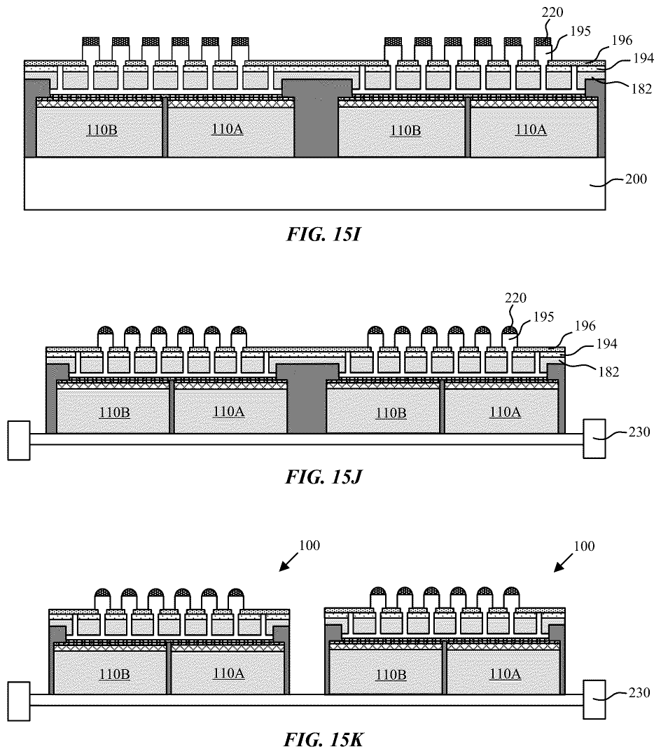

FIGS. 15A-15K are schematic cross-sectional side view illustrations of a sequence for fabricating an integrated circuit structure in accordance with an embodiment. As shown in FIG. 15A the sequence can begin with a base substrate 182, such as a silicon wafer, glass panel, etc. In the exemplary embodiment illustrated, a plurality of partially formed through vias 190 (e.g., copper vias) are partially formed through a thickness of the base substrate 182, followed by formation of routing layer 184, which may be one or more dielectric and metal wiring layers in accordance with embodiments. Metal bond pads 142 and a bonding interface layer 140 (e.g., silicon oxide, silicon nitride, silicon carbon nitride, etc.) can then be formed. The top surface may then be planarized as shown in FIG. 15B to form a planar bonding surface 132 with the metal bond pads 142 and bonding interface layer 140. One or more global or local component edge recesses 186 can then be formed to a desired depth as shown in FIG. 15C using a suitable technique such as plasma etching. While the component edge recess 186 depth illustrated in FIG. 15C is into the base substrate 182, this is exemplary and embodiments are not so limited. One or more IC dies 110, or die sets of IC dies 110A, 110B for example, can then be fusion bonded or hybrid bonded directly to the planar bonding surface 132 as shown in FIG. 15D.

The bonded structure may then be molded as shown in FIG. 15E to encapsulate the IC dies and fill the component edge recesses 186, followed by optional grinding operation to thin the IC die thicknesses as shown in FIG. 15F. Following molding and optional thinning, the structure can be flipped and bonded to a carrier substrate 200, such a silicon wafer, glass panel, metal panel, etc. as shown in FIG. 15G to provide support for additional processing. Additional grinding and planarization can then be performed to thin the base substrate 182, exposing through vias 190 as shown in FIG. 15H. This may be followed by deposition of one or more passivation layers 194, 196 such as silicon nitride and polyimide, respectively, and additional plating to form terminals 195 in connection with the through vias 190 as shown in FIG. 15I. Solder bumps 220 (or solder tips) can then be applied to terminals 195. At this point the structure can be debonded from the carrier substrate 200 and transferred to a frame 230 wherein the solder bumps can be reflowed as shown in FIG. 15J followed by singulation of multiple integrated circuit structures 100 (or packages) as shown in FIG. 15K for example by mechanical sawing.

In utilizing the various aspects of the embodiments, it would become apparent to one skilled in the art that combinations or variations of the above embodiments are possible for forming an IC structure and IC die including one or more edge recesses to accommodate molding compound. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An integrated circuit structure comprising:
an integrated circuit (IC) die including a first bonding surface, a first lateral edge and a first edge recess in the first bonding surface;
an electronic component including a second bonding surface bonded directly to the first bonding surface; and
a molding compound that spans across the electronic component and the first lateral edge, and fills the first edge recess.

2. The integrated circuit structure of claim 1, wherein the first edge recess is characterized by a first width that extends from the first lateral edge to a first interior edge, and a first depth that extends from the first bonding surface to a first roof.

3. The integrated circuit of claim 2, wherein the first width is a greater distance than the first depth.

4. The integrated circuit structure of claim 2, wherein the IC die includes:
a semiconductor layer;
a back-end-of-the-line (BEOL) build-up structure on the semiconductor layer; and
a bonding interface layer on the BEOL build-up structure;
wherein the first depth of the first edge recess spans the bonding interface layer, the BEOL build-up structure, and into the semiconductor layer.

5. The integrated circuit of claim 4, wherein the BEOL build-up structure includes a seal ring adjacent to the first interior edge, and the first width of the first edge recess does not extend to the seal ring.

6. The integrated circuit structure of claim 4, wherein:
the IC die includes a second edge recess;
the second edge recess spans underneath the first BEOL build-up structure;
the second edge recess is characterized by a second width that extends from the first interior edge of the first recess to a second interior edge, and a second depth that extends from the first bonding surface to a second roof; and
the molding compound fills the second edge recess.

7. The integrated circuit structure of claim 6, wherein the BEOL build-up structure includes a seal ring adjacent to the first interior edge, and the second width of the second recess extends underneath the seal ring.

8. The integrated circuit structure of claim 2, wherein the IC die includes:
a semiconductor layer;
a back-end-of-the-line (BEOL) build-up structure on the semiconductor layer; and
a bonding interface layer on the BEOL build-up structure;
wherein the first roof of the first edge recess is underneath the BEOL build-up structure.

9. The integrated circuit of claim 8, wherein the BEOL build-up structure includes a seal ring adjacent to the first interior edge, and the width of first recess does not extend to the seal ring.

10. The integrated circuit of claim 1, wherein the first bonding surface is hybrid bonded with the second bonding surface.

11. The integrated circuit of claim 10, wherein the first bonding surface is fusion bonded with the second bonding surface.

12. The integrated circuit of claim 1, wherein:
the electronic component includes a component edge recess in the second bonding surface; and
the molding compound fills the component edge recess.

13. An integrated circuit die comprising:
a first planar bonding surface, a first lateral edge and a first edge recess in the first planar bonding surface;
wherein the first edge recess is characterized by a first width that extends from the first lateral edge to a first interior edge, and a first depth that extends from the first planar bonding surface to a first roof.

14. The integrated circuit die of claim 13, wherein the first width is a greater distance than the first depth.

15. The integrated circuit die of claim 13, further comprising:
a semiconductor layer;
a back-end-of-the-line (BEOL) build-up structure on the semiconductor layer; and
a bonding interface layer on the BEOL build-up structure;
wherein the first depth of the first edge recess spans the bonding interface layer, the BEOL build-up structure, and into the semiconductor layer.

16. The integrated circuit die of claim 15, wherein the BEOL build-up structure includes a seal ring adjacent to the first interior edge, and the first width of the first edge recess does not extend to the seal ring.

17. The integrated circuit die of claim 15:
further comprising a second edge recess;
wherein the second edge recess spans underneath the first BEOL build-up structure; and
wherein the second edge recess is characterized by a second width that extends from the first interior edge of the first recess to a second interior edge, and a second depth that extends from the first bonding surface to a second roof.

18. The integrated circuit die of claim 17, wherein the BEOL build-up structure includes a seal ring adjacent to the first interior edge, and the second width of the second recess extends underneath the seal ring.

19. The integrated circuit die of claim 13, further comprising:
a semiconductor layer;
a back-end-of-the-line (BEOL) build-up structure on the semiconductor layer; and
a bonding interface layer on the BEOL build-up structure;
wherein the first roof of the first edge recess is underneath the BEOL build-up structure.

20. The integrated circuit die of claim 19, wherein the BEOL build-up structure includes a seal ring adjacent to the first interior edge, and the width of first recess does not extend to the seal ring.

21. The integrated circuit die of claim 13, wherein the first planar bonding surface spans a plurality of metal bond pads and a bonding interface layer.

22. An integrated circuit structure comprising:
an integrated circuit (IC) die including a first bonding surface and a first perimeter edge;
an electronic component including a second bonding surface and a component edge recess in the second bonding surface, wherein the second bonding surface is bonded directly to the first bonding surface; and
a molding compound that spans across the electronic component and the first perimeter edge, and fills the component edge recess.

23. The integrated circuit structure of claim 22, wherein the component edge recess surrounds the first perimeter edge of the IC die.

24. The integrated circuit structure of claim 23, wherein the component edge recess is located adjacent a corner of the IC die.

25. The integrated circuit structure of claim 1, wherein the component edge recess is characterized by a width that extends from a component lateral edge to a component interior edge, and a first depth that extends from the second bonding surface to a floor.

26. The integrated circuit structure of claim 22, wherein the electronic component comprises a plurality of through silicon vias.

27. The integrated circuit of claim 22, wherein:
the die includes a first edge recess in the first bonding surface; and
the molding compound fills the first edge recess.
